(19) United States
(12) Patent Application Publication
(10) Pub. No.: US 2011/0139489 A1
(43) Pub. Date: Jun. 16, 2011

(54) PRINTED CIRCUIT BOARD

(75) Inventors: Hee-Soo Yoon, Suwon-si (KR); Dong-Hwan Lee, Suwon-si (KR); Kyoung-Ho Lee, Hwasung-si (KR); Yoon-Dong Kim, Yongin-si (KR); Su-Bong Jang, Anyang-si (KR)

(73) Assignee: SAMSUNG ELECTRO-MECHANICS CO., LTD.

(21) Appl. No.: 12/772,469

(22) Filed: May 3, 2010

(30) Foreign Application Priority Data
Dec. 10, 2009 (KR) 10-2009-0122512

(51) Int. Cl. H05K 1/00

(52) U.S. Cl. 174/250

(57) ABSTRACT

A printed circuit board is disclosed. The printed circuit board in accordance with an embodiment of the present invention can include an insulation substrate, a first ground, which is formed on one surface of the insulation substrate and connected to a first power source, a second ground, which is formed on one surface of the insulation substrate and connected to a second power source, a separator, which separates the first ground from the second ground, a first signal line, which is stacked on at least one of the first ground and the second ground, and a second signal line, which is stacked on at least one of the first ground and the second ground and is adjacent to the first signal line. The separator can include a curved part, which is bent in between the first signal line and the second signal line.

### CROSS-REFERENCE TO RELATED APPLICATIONS

This application claims the benefit of Korean Patent Application No. 10-2009-0122512, filed with the Korean Intellectual Property Office on Dec. 10, 2009, the disclosure of which is incorporated herein by reference in its entirety.

### BACKGROUND

1. Technical Field

The present invention is related to a printed circuit board.

2. Description of the Related Art

In step with the trends toward highly integrated package substrates with higher functionalities on which electronic components are mounted, there is a growing demand for highly integrated circuit patterns that are formed on the package substrates. As the circuit patterns become densified, interruption between signals being applied to the circuit patterns may occur, and thus the circuit patterns may generate electromagnetic waves.

A signal line formed on a printed circuit board transmits a data signal while interchanging electromagnetic energy with its ground. In the printed circuit board, the signal line and a power source are typically formed on different layers of the board. Since the electronic components mounted on each substrate require different power voltages, the power sources supplying different power voltages have to be connected to different grounds.

The signal line is overlapped with the ground, where an insulation layer is interposed between the signal lines and the ground. Here, electromagnetic distortion occurs between two adjacent signal lines, causing an interruption between signals transmitted through the signal lines. Moreover, if the two adjacent signal lines are overlapped with a separated portion of the ground, the coupling coefficient may increase in the overlapped area. As a result, signal attenuation becomes severe, increasing the amount of electromagnetic wave generation.

### SUMMARY

The present invention provides a printed circuit board that can reduce electromagnetic distortion generated between adjacent two signal lines.

The present invention also provides a printed circuit board that makes adjacent two signal lines cross a separator at different locations from each other to cause a phase difference between signals transmitted through the two signal lines, thereby reducing a coupling coefficient.

The present invention provides a printed circuit board that can reduce the attenuation of a signal transmitted through adjacent two signal lines.

An aspect of the present invention provides a printed circuit board. The printed circuit board in accordance with an embodiment of the present invention can include an insulation substrate, a first ground, which is formed on one surface of the insulation substrate and connected to a first power source, a second ground, which is formed on one surface of the insulation substrate and connected to a second power source, a separator, which separates the first ground from the second ground, a first signal line, which is stacked on at least one of the first ground and the second ground, and a second signal line, which is stacked on at least one of the first ground and the second ground and is adjacent to the first signal line. The separator can include a curved part, which is bent in between the first signal line and the second signal line.

The curved part can be parallel to the first signal line or the second signal line.

The first signal line can be parallel to the second signal line.

The first signal line and the second signal line can be formed on a same planar surface.

The printed circuit board can further include an insulation layer, which covers the first ground and the second ground. One of the first signal line and the second signal line can be formed over the insulation layer.

At least one of the first signal line and the second signal line can be formed on the other surface of the insulation substrate.

Another aspect of the present invention provides a printed circuit board. The printed circuit board in accordance with an embodiment of the present invention can include a first insulation substrate, which has a first ground, a second ground and a separator, and a second insulation substrate, which has a first signal line and a second signal line formed thereon. The first ground is connected to a first power source, the second ground is connected to a second power source, and the separator separates the first ground from the second ground. The first signal line is stacked on at least one of the first ground and the second ground, and the second signal line is adjacent to the first signal line. The separator can include a curved part, which is bent in between the first signal line and the second signal line.

The curved part can be parallel to the first signal line or the second signal line.

The first signal line can be parallel to the second signal line.

The printed circuit board can further include a third insulation substrate, which has the first power source and the second power source formed thereon.

Yet another aspect of the present invention provides a printed circuit board. The printed circuit board in accordance with an embodiment of the present invention can include a first insulation substrate, which has a first ground, a second ground and a separator, a second insulation substrate, which has a first signal line formed thereon, and a third insulation substrate, which has a second signal line formed thereon. The first ground is connected to a first power source, the second ground is connected to a second power source, and the separator separates the first ground from the second ground. The first signal line is stacked on at least one of the first ground and the second ground. The second signal line is stacked on at least one of the first ground and the second ground and parallel to the first signal line. The separator can include a curved part, which is bent in between the first signal line and the second signal line.

Additional aspects and advantages of the present invention will be set forth in part in the description which follows, and in part will be obvious from the description, or may be learned by practice of the invention.

### BRIEF DESCRIPTION OF THE DRAWINGS

FIG. 1 is a plan view of a printed circuit board in accordance with a first embodiment of the present invention.

FIG. 2 is a cross-sectional view across the transversal line I-I′ of the printed circuit board shown in FIG. 1.

FIG. 3 is a brief depiction of the forms of phase of signals applied to a first signal line and a second signal line of the printed circuit board shown in FIG. 1.

FIG. 4 is a waveform graph comparing the magnitudes of signals per frequency applied to the first signal line and the second signal line of the printed circuit board shown in FIG. 1 and the magnitudes of signals per frequency applied to a first signal line and a second signal line of a printed circuit board in which a curved part is not formed.

FIGS. 5 to 7 are plan views illustrating cross-sectional views of a printed circuit board in accordance with second to fourth embodiments of the present invention.

FIGS. 8 to 11 are cross-sectional views illustrating plan views of a printed circuit board in accordance with fifth to eighth embodiments of the present invention.

### DETAILED DESCRIPTION

As the invention allows for various changes and numerous embodiments, particular embodiments will be illustrated in the drawings and described in detail in the written description. However, this is not intended to limit the present invention to particular modes of practice, and it is to be appreciated that all changes, equivalents, and substitutes that do not depart from the spirit and technical scope of the present invention are encompassed in the present invention. In the description of the present invention, certain detailed descriptions of related art are omitted when it is deemed that they may unnecessarily obscure the essence of the invention.

A printed circuit board according to certain embodiments of the present invention will be described below in more detail with reference to the accompanying drawings. Those components that are the same or are in correspondence are rendered the same reference numeral regardless of the figure number, and redundant descriptions are omitted.

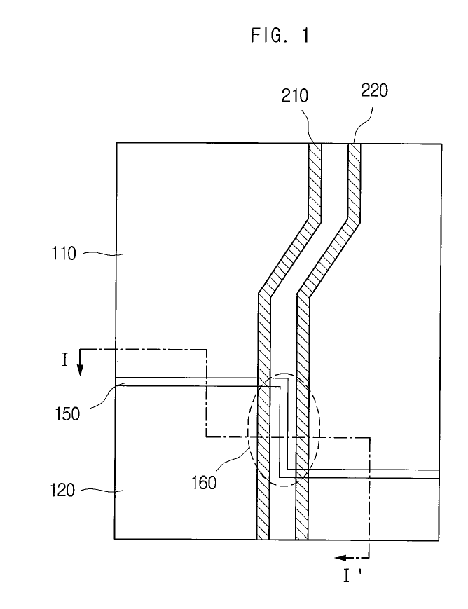

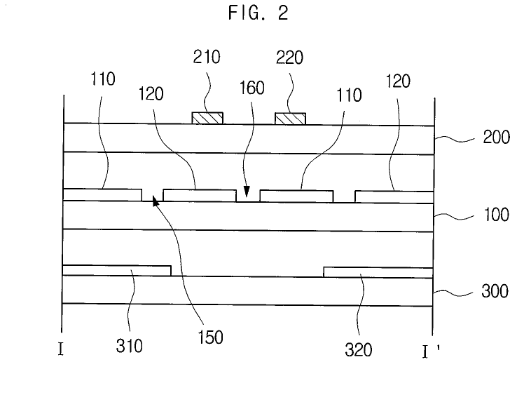

FIG. 1 is a plan view of a printed circuit board in accordance with a first embodiment of the present invention, and FIG. 2 is a cross-sectional view across the transversal line I-I′ of the printed circuit board shown in FIG. 1.

Referring to FIGS. 1 and 2, the printed circuit board in accordance with a first embodiment of the present invention can include a first insulation substrate 100, a second insulation substrate 200, a third insulation substrate 300, a first signal line 210, a second signal line 220, a first ground 110, a second ground 120, a first power source 310, a second power source 320, a separator 150 and a curved part 160.

Specifically, the first ground 110 and the second ground 120 are formed on the first insulation substrate 100. The first ground 110 and the second ground 120 can be formed on a same planar surface.

The first ground 110 is formed to occupy a certain area on one surface of the first insulation substrate 100. The second ground 120 is formed to occupy a certain area on one surface of the first insulation substrate 100. The first ground 110 and the second ground 120 can be formed with a surface area that is sufficient to stably operate the first power source 310 and the second power source 320, which are connected to the first ground 110 and the second ground 120, respectively.

The first ground 110 and the second ground 120 are separated electrically and physically from each other by the separator 150. In order to increase the surface areas of the first ground 110 and the second ground 120, the separator 150 can be formed in the form of a slit.

The first signal line 210 and the second signal line 220 are formed on the second insulation substrate 200. The first signal line 210 and the second signal line 220 apply signals to electronic components (not shown). Here, the signals applied to the first signal line 210 and the second signal line 220 can have a same frequency or a frequency of 2N (N being a natural number).

The first power source 310 and the second power source 320 are formed on the third insulation substrate 300. The first power source 310 and the second power source 320 supply voltages of different levels. Specifically, the first power source 310 supplies a first voltage, and the second power source 320 supplies a second voltage.

The first power source 310 and the second power source 320 supply voltages needed to operate the electronic components. One side of the first power source 310 is connected to an electronic component that is operated by the first voltage, and the other side of the first poser source 310 is connected to the first ground 110. One side of the second power source 320 is connected to an electronic component that is operated by the second voltage, and the other side of the second power source 320 is connected to the second ground 120

Here, the first power source 310 and the first ground 110 can be electrically connected to each other by, for example, a through-hole, and the second power source 320 and the second ground 120 can also be electrically connected to each other by, for example, a through-hole.

The second insulation substrate 200 is placed above the first insulation substrate 100, and the third insulation substrate 300 is placed below the first insulation substrate 100. It shall be obvious, however, that the present invention is not restricted to this embodiment, and it is also possible that the second insulation substrate 200 is placed below the first insulation substrate 100, and the third insulation substrate 300 above the first insulation substrate 100.

Specifically, the second insulation substrate 200 is stacked over the first insulation substrate 100. Accordingly, the first signal line 210 and the second signal line 220 are overlapped with the first ground 110 and the second ground 120, respectively. Here, the first signal line 210 and the second signal line 220 can be stacked to cross the separator 150.

The curved part 160 is interposed between the first signal line 210 and the second signal line 220. The curved part 160 generates a phase difference between a first signal, which is transmitted through the first signal line 210, and a second signal, which is transmitted through the second signal line 220. Specifically, as illustrated in FIG. 1, the curved part 160 makes the point where the first signal line 210 intersects the separator 150 and the point where the second signal line 220 intersects the separator 150 different from each other so that a phase difference can be generated between the first signal and the second signal.

Therefore, a coupling coefficient between signals being transmitted through the first signal line 210 and the second signal line 220 can be reduced. Once the coupling coefficients between the signals transmitted through the first signal line 210 and the second line 220 are reduced, attenuation of the signals can be reduced. Moreover, the amount of electromagnetic wave radiation can be reduced.

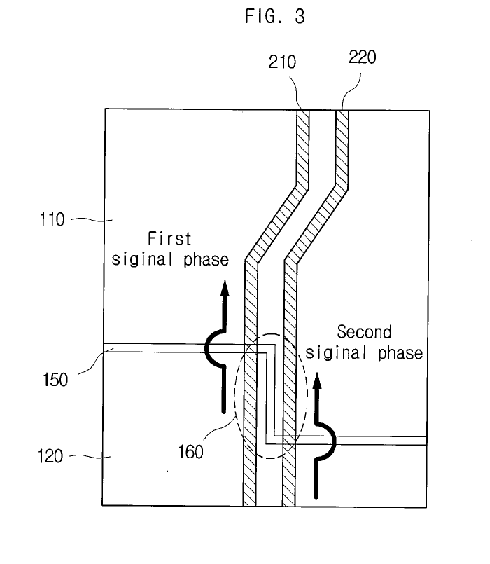

FIG. 3 is a brief depiction of the forms of phase of signals applied to the first signal line and the second signal line of the printed circuit board shown in FIG. 1.

Referring to FIG. 3, the first signal, which is transferred through the first signal line 210, and the second signal, which is transferred through the second signal line 220, generate a phase difference at the separator 150. Therefore, interruption between signals can be reduced by reducing the coupling coefficient of the first signal and the second signal.

In one example, the first signal has much less attenuation at the point where the first signal line 210 intersects with the separator 150 since the coupling coefficient is reduced by the second signal. Also, the second signal has much less attenuation at the point where the second signal line 220 intersects with the separator 150 since the coupling coefficient is reduced by the first signal.

In other words, if signals are applied to the first signal line 210 and the second signal line 220, a phase difference occurs between the signals transmitted to the first signal line 210 and the second signal line 220, respectively. As a result, the coupling coefficient between the first signal, which is transmitted to the first signal line 210, and the second signal, which is transmitted to the second signal line 220, can be reduced. Accordingly, the amount of electromagnetic wave radiation can be reduced by the first signal and the second signal transmitted through the first signal line 210 and the second signal line 220.

Therefore, attenuation of the first signal and the second signal, which are respectively transmitted through the first signal line 210 and the second signal line 220, can be reduced, thereby increasing the signal transmitting efficiency.

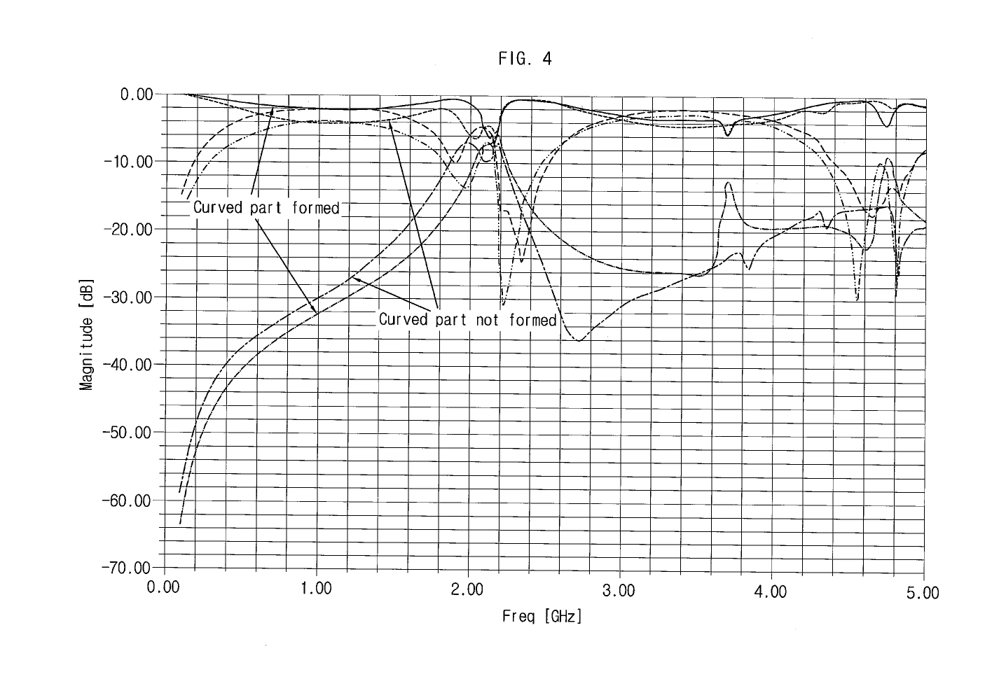

FIG. 4 is a waveform graph comparing the magnitudes of signals per frequency applied to the first signal line and the second signal line of the printed circuit board shown in FIG. 1 and the magnitudes of signals per frequency applied to a first signal line and a second signal line of a printed circuit board in which a curved part is not formed.

As illustrated in FIG. 4, if a signal at a frequency of 200 MHz to 2 GHz is applied to the printed circuit board in accordance with a first embodiment of the present invention, there is a signal difference of about 2 dB, compared to the case of applying the signal to a printed circuit board in which the curved part is not formed.

Therefore, the printed circuit board in accordance with a first embodiment of the present invention can have much less attenuation when the signals are transmitted.

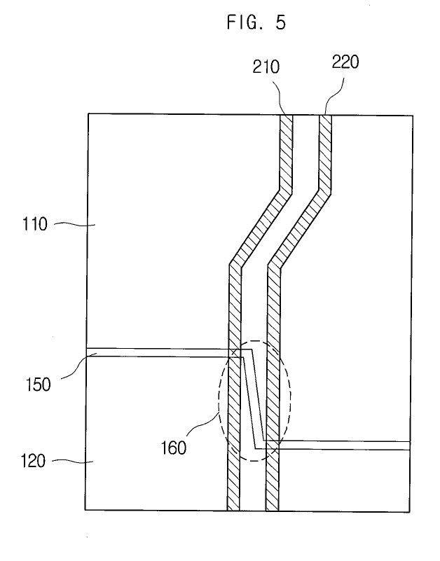

FIG. 5 is a plan view of a printed circuit board in accordance with a second embodiment of the present invention.

Since the printed circuit board shown in FIG. 5 has the same configuration as that of the printed circuit board shown in FIG. 1, except that the curved part 160 is formed diagonally, and thus any redundant description with respect to the same configuration will be omitted.

Referring to FIG. 5, the separator 150 intersects with the first signal line 210 and with the second signal line 220, and the curved part 160 is interposed between the first signal line 210 and the second signal line 220. The curved part 160 is formed diagonally.

The curved part 160 makes the first signal line 210 and the second signal line 220 cross the separator 150 at locations that are different from each other.

Therefore, a phase difference occurs between the first signal, which is transmitted to the first signal line 210, and the second signal, which is transmitted to the second signal line 220, and thus the coupling coefficient can be reduced. Also, since the coupling coefficient of the first signal and the second signal is reduced, signal transmission loss can be reduced. Moreover, since the coupling coefficient of the first signal and the second signal is reduced, the amount of electromagnetic wave radiation can be reduced, and thus electromagnetic interference on peripheral devices, for example, electronic components, can be reduced.

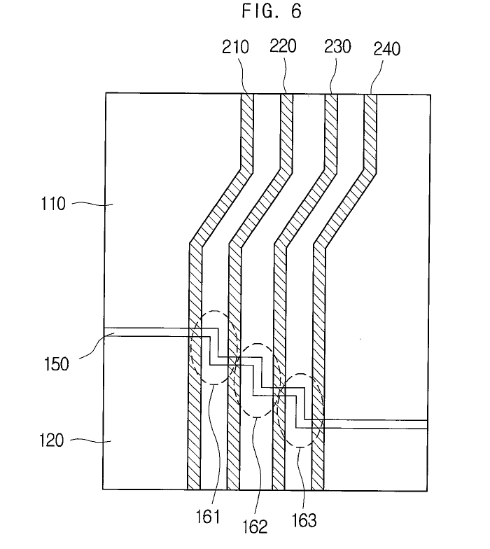

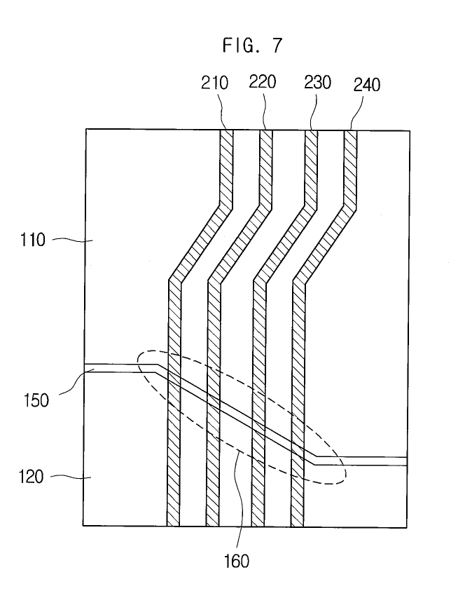

FIG. 6 is a plan view of a printed circuit board in accordance with a third embodiment of the present invention, and FIG. 7 is a plan view of a printed circuit board in accordance with a fourth embodiment of the present invention. In FIGS. 6 and 7, a plurality of signal lines are formed on the second insulation substrate 200.

As illustrated in FIGS. 6 and 7, the printed circuit board in accordance with a third embodiment of the present invention can include the first signal line 210, the second signal line 220, a third signal line 230, a fourth signal line 240, the first ground 110, the second ground 120, the separator 150, a first curved part 161, a second curved part 162 and a third curved part 163. Here, the first ground 110, the second ground 120, the separator 150, the first curved part 161, the second curved part 162 and the third curved part 163 can be formed on the first insulation substrate 100, and the first to fourth signal lines 210 to 240 can be formed on the second insulation substrate 200. It shall be obvious, however, that the present invention is not restricted to this embodiment, and it is also possible that the first to fourth signal lines 210 to 240 are formed on the first insulation substrate 100. It is also possible that some of the first to fourth signal lines 210 to 240 are formed on the first insulation substrate 100, and the remaining signal lines are formed on the second insulation substrate 200.

Specifically, each of the first to fourth signal lines 210 to 240 is stacked on both the first ground 110 and the second ground 120.

The separator 150 electrically separates the first ground 110 from the second ground 120. The separator 150 can include the first to third curved parts 161 to 163.

The first curved part 161 is interposed between the first signal line 210 and the second signal line 220, and the second curved part 162 is interposed between the second signal line 220 and the third signal line 230. The third curved part 163 is interposed between the third signal line 230 and the fourth signal line 240.

As illustrated in FIG. 6, the curved parts 161 to 163 can be formed in the shape of steps. Also, as illustrated in FIG. 7, the curved part 160 can be formed diagonally.

The first to third curved parts 161 to 163 make the first signal line 210, the second signal line 220, the third signal line 230 and the fourth signal line 240 cross the separator 150 at different locations from one another, causing a phase difference between the signals transmitted through the first to fourth signal lines 210 to 240.

Therefore, the coupling coefficients of the signals transmitted through the first to fourth signal lines 210 to 240 can be reduced, and thus signal transmission loss can be reduced. Since the coupling coefficients of the signals are reduced, the amount of electromagnetic wave radiation can be reduced, and thus electromagnetic interference on peripheral devices, for example, electronic components, can be reduced.

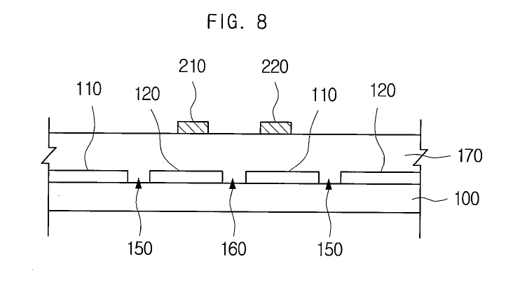

FIG. 8 is a cross-sectional view of a printed circuit board in accordance with a fifth embodiment of the present invention.

Since the printed circuit board shown in FIG. 8 has the same structure as the plan view of the printed circuit board shown in FIG. 1, except the stacking structure, the following description will refer to the plan view structure of the printed circuit board shown in FIG. 1.

Referring to FIG. 8, the printed circuit board in accordance with a fifth embodiment of the present invention can include the first insulation substrate 100, the first ground 110, the second ground 120, the first signal line 210, the second signal line 220, an insulation layer 170, the separator 150 and the curved part 160. Here, the printed circuit board of the present embodiment can include a second insulation substrate (not shown) on which a power source (not shown) is formed. Here, the power source can include a first power source, which is electrically connected to the first ground 110, and a second power source, which is electrically connected to the second ground 120.

Specifically, the first ground 110, the second ground 120, the separator 150 and the curved part 160 are formed on the first insulation substrate 100. Since the first ground 110, the second ground 120, the separator 150 and the curbed part 160 have the same configuration as those shown in FIGS. 1 to 7, any redundant description with respect to the same configuration will be omitted.

The insulation layer 170 is formed over the first ground 110 and the second ground 120. The insulation layer 170 can be made of a material, for example, oxides or nitrides.

The first signal line 210 and the second signal line 220 are formed on the insulation layer 170. Each of the first signal line 210 and the second signal line 220 is stacked on both the first ground 110 and the second ground 120. The first signal line 210 and the second signal line 220 also cross the separator 150. Here, as illustrated in FIG. 1, since the first signal line 210 and the second signal line cross the separator 150, a phase difference occurs in the signals applied through the first signal line 210 and the second signal line 220.

Therefore, the coupling coefficient between the signals being transmitted through the first signal line 210 and the second signal line 220 can be reduced, and thus signal transmission loss can be reduced. Moreover, since the coupling coefficient of the signals is reduced, the amount of electromagnetic wave radiation can be reduced, and thus electromagnetic interference on peripheral devices, for example, electronic components, can be reduced.

Also, the stacking structure of the stacked printed circuit board can be reduced by forming the first signal line 210 and the second signal line 220 on the first insulation substrate 100.

The curved part 160 in FIG. 8 can be the shape shown in FIG. 1 or FIG. 5. It shall be obvious, however, that the present invention is not restricted to this embodiment and that various other shapes are also possible.

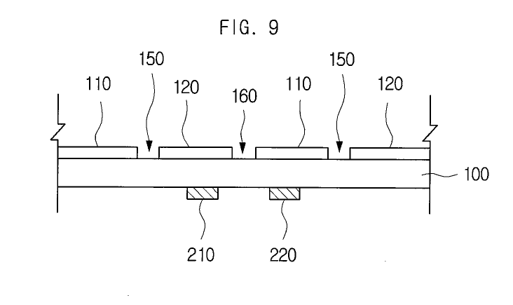

FIG. 9 is a cross-sectional view of a printed circuit board in accordance with a sixth embodiment of the present invention.

Since the printed circuit board shown in FIG. 9 has the same structure as the plan view of the printed circuit board shown in FIG. 1, except the stacking structure, the following description will refer to the plan view structure of the printed circuit board shown in FIG. 1.

Referring to FIG. 9, the printed circuit board in accordance with a sixth embodiment of the present invention has the first insulation substrate 100 and the first signal line 210, the second signal line 220, the first ground 110, the second ground 120, the separator 150 and the curved part 160 that are formed on the first insulation substrate 100.

Specifically, the first ground 110, the second ground 120, the separator 150 and the curved part 160 are formed on one surface of the first insulation substrate 100, and the first signal line 210 and the second signal line 220 are formed on the other surface of the first insulation substrate 100.

The first signal line 210 and the second signal line 220 are arranged to cross the separator 150. Also, the first signal line 210 and the second signal line 220 can be made to cross the separator 150 at different locations from each other by interposing the curved part 160 between the first signal line 210 and the second signal line 220.

The curved part 160 in FIG. 9 can be the shape shown in FIG. 1 or FIG. 5. It shall be obvious, however, that the present invention is not restricted to this embodiment and that various other shapes are also possible.

Therefore, the coupling coefficient between the signals being transmitted through the first signal line 210 and the second signal line 220 can be reduced, and thus signal transmission loss can be reduced. Moreover, since the coupling coefficient of the signals is reduced, the amount of electromagnetic wave radiation can be reduced, and thus electromagnetic interference on peripheral devices, for example, electronic components, can be reduced.

Also, the stacking structure of the stacked printed circuit board can be reduced by forming the first signal line 210 and the second signal line 220 on a lower surface of the first insulation substrate 100.

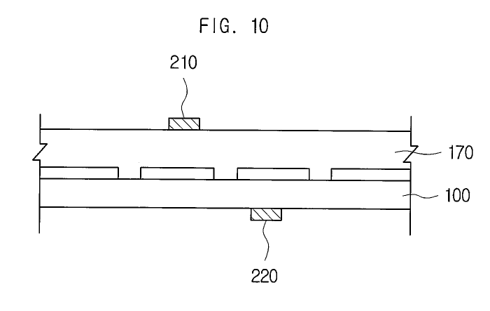

FIG. 10 is a cross-sectional view of a printed circuit board in accordance with a seventh embodiment of the present invention. The printed circuit board in FIG. 10 has the same structure as the printed circuit board shown in FIG. 8, except that the first signal line 210 is formed on an upper side top of the insulation layer 170 and the second signal line 220 is formed on a lower surface of the first insulation substrate 100.

Referring to FIG. 10, the printed circuit board in accordance with a seventh embodiment of the present invention has the first signal line 210 formed on the upper side of the insulation layer 170. The second signal line 220 is formed on the lower surface of the first insulation substrate 100. The first signal line 210 and the second signal line 220 can be arranged to cross the separator 150. Here, the first signal line 210 and the second signal line 220 can be made to cross the separator 150 at locations that are different from each other, by interposing the curved part 160 between the first signal line 210 and the second signal line 220.

The curved part 160 in FIG. 10 can be the shape shown in FIG. 1 or FIG. 5. It shall be obvious, however, that the present invention is not restricted to this embodiment and that various other shapes are also possible.

Therefore, the coupling coefficient between the signals being transmitted through the first signal line 210 and the second signal line 220 can be reduced, and thus signal transmission loss can be reduced. Moreover, since the coupling coefficient of the signals is reduced, the amount of electromagnetic wave radiation can be reduced, and thus electromagnetic interference on peripheral devices, for example, electronic components, can be reduced.

Also, the stacking structure of the stacked printed circuit board can be reduced by forming the first signal line 210 and the second signal line 220 on the first insulation substrate 100.

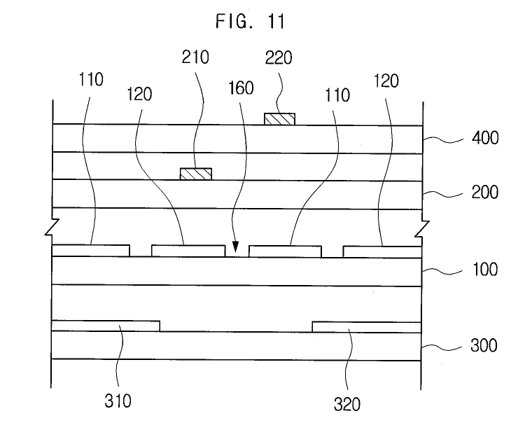

FIG. 11 is a cross-sectional view of a printed circuit board in accordance with an eighth embodiment of the present invention. The printed circuit board shown in FIG. 11 has the same configuration as that of the printed circuit board shown in FIG. 2, except that the second signal line 220 is formed on a fourth insulation substrate 400.

Referring to FIG. 11, the printed circuit board in accordance with an eighth embodiment of the present invention can include the first insulation substrate 100, the second insulation substrate 200, the third insulation substrate 300, the fourth insulation substrate 400, the first signal line 210, the second signal line 220, the first ground 110, the second ground 120, the separator 150 and the curved part 160.

Specifically, the first ground 110, the second ground 120, the separator 150 and the curved part 160 are formed on the first insulation substrate 100.

The first signal line 210 is formed on the second insulation substrate 200. The first signal line 210 is stacked on both the first ground 110 and the second ground 120. The first signal line 210 is arranged to cross the separator 150.

The first power source 310 and the second power source 320 are formed on the third insulation substrate 300. The first power source 310 is electrically connected to the first ground 110, and the second power source 320 is electrically connected to the second ground 120.

The second signal line 220 is formed on the fourth insulation substrate 400. The second signal line 220 is stacked on both the first ground 110 and the second ground 120 and is arranged to cross the separator 150. The second signal line 220 can be parallel to the first signal line 210.

Here, the curved part 160 makes the first signal line 210 and the second signal line 220 intersect with the separator 150 at different locations from each other, and thus a phase difference can occur between the signals transmitted through the first signal line 210 and the second signal line 220.

The curved part 160 in FIG. 11 can be the shape shown in FIG. 1 or FIG. 5. It shall be obvious, however, that the present invention is not restricted to this embodiment and that various other shapes are also possible.

Therefore, the coupling coefficient between the signals being transmitted through the first signal line 210 and the second signal line 220 can be reduced, and thus signal transmission loss can be reduced. Moreover, since the coupling coefficient of the signals is reduced, the amount of electromagnetic wave radiation can be reduced, and thus electromagnetic interference on peripheral devices, for example, electronic components, can be reduced.

Although steps and diagonal lines have been described as examples of the curved parts of the printed circuit boards shown in FIGS. 1 to 11, it shall be appreciated that the shape of the curved part is not restricted to the shapes described in these particular embodiments and that it is also possible to form the curved part in the shape of a curved line.

While the spirit of the present invention has been described in detail with reference to particular embodiments, the embodiments are for illustrative purposes only and shall not limit the present invention. It is to be appreciated that those skilled in the art can change or modify the embodiments without departing from the scope and spirit of the present invention.

What is claimed is:

1. A printed circuit board comprising:
an insulation substrate;
a first ground formed on one surface of the insulation substrate and connected to a first power source;
a second ground formed on one surface of the insulation substrate and connected to a second power source;
a separator separating the first ground from the second ground;
a first signal line stacked on at least one of the first ground and the second ground; and
a second signal line stacked on at least one of the first ground and the second ground, the second signal line being adjacent to the first signal line,
wherein the separator comprises a curved part bent in between the first signal line and the second signal line.

2. The printed circuit board of claim 1, wherein the curved part is parallel to the first signal line or the second signal line.

3. The printed circuit board of claim 1, wherein the first signal line is parallel to the second signal line.

4. The printed circuit board of claim 1, wherein the first signal line and the second signal line are formed on a same planar surface.

5. The printed circuit board of claim 1, further comprising an insulation layer covering the first ground and the second ground,
wherein one of the first signal line and the second signal line is formed over the insulation layer.

6. The printed circuit board of claim 1, wherein at least one of the first signal line and the second signal line is formed on the other surface of the insulation substrate.

7. A printed circuit board comprising:
a first insulation substrate having a first ground, a second ground and a separator, the first ground connected to a first power source, the second ground connected to a second power source, the separator separating the first ground from the second ground; and
a second insulation substrate having a first signal line and a second signal line formed thereon, the first signal line stacked on at least one of the first ground and the second ground, the second signal line being adjacent to the first signal line,
wherein the separator comprises a curved part bent in between the first signal line and the second signal line.

8. The printed circuit board of claim 7, wherein the curved part is parallel to the first signal line or the second signal line.

9. The printed circuit board of claim 7, wherein the first signal line is parallel to the second signal line.

10. The printed circuit board of claim 7, further comprising a third insulation substrate having the first power source and the second power source formed thereon.

11. A printed circuit board comprising:
a first insulation substrate having a first ground, a second ground and a separator, the first ground connected to a first power source, the second ground connected to a second power source, the separator separating the first ground from the second ground;
a second insulation substrate having a first signal line formed thereon, the first signal line stacked on at least one of the first ground and the second ground; and
a third insulation substrate having a second signal line formed thereon, the second signal line stacked on at least one of the first ground and the second ground and being parallel to the first signal line,
wherein the separator comprises a curved part bent in between the first signal line and the second signal line.
